(19) United States
(12) Patent Application Publication
(10) Pub. No.: US 2012/0125419 A1
(43) Pub. Date: May 24, 2012

(54) PHOTOACTIVE COMPONENT COMPRISING AN INVERTED LAYER SEQUENCE, AND METHOD FOR THE PRODUCTION OF SAID COMPONENT

(75) Inventors: Martin Pfeiffer, Dresden (DE); Christian Uhrich, Dresden (DE); Bert Maennig, Dresden (DE); Karsten Walzer, Dresden (DE); David Wynands, Schloddwitz (DE)

(73) Assignee: HELIATEK GMBH, Dresden (DE)

(21) Appl. No.: 13/375,597

(22) PCT Filed: Jun. 7, 2010
(86) PCT No.: PCT/EP10/57889

§ 371 Date: Feb. 8, 2012

(30) Foreign Application Priority Data
Jun. 5, 2009 (DE) 10 2009 024 294.5
Oct. 29, 2009 (DE) 10 2009 051 142.3

(51) Int. Cl. H01L 51/44; H01L 31/0687

(52) U.S. Cl. 136/255; 136/263

(57) ABSTRACT

A photoactive component comprising organic layers, in particular a solar cell comprising a photoactive i-layer system, contains at least one mixed layer. The mixed layer contains at least one donator material and one acceptor material, and thus forms a donator-acceptor system. The donator material and the acceptor material of the mixed layer are non-polymer materials. In a vacuum, the donator material has an evaporation temperature which is at least 150° C. lower than the evaporation temperature of the acceptor material and has an inverted layer sequence with an n-i-p, i-p, or n-i structure of an n-layer, i-layer, or p-layer system respectively. The organic photoactive i-layer system is applied directly onto the cathode or onto an electron-conducting n-material system.

The invention relates to a photoactive component comprising organic layers, more particularly a solar cell according to the preamble of claim 1.

Since the demonstration of the first organic solar cell having an efficiency in the percent range by Tang et al. 1986 [C. W. Tang et al. Appl. Phys. Lett. 48, 183 (1986)], organic materials have been investigated intensively for various electronic and optoelectronic components. Organic solar cells consist of a sequence of thin layers (typically 1 nm to 1 μm) composed of organic materials, which are preferably applied by vapor deposition in a vacuum or by spin-coating from a solution. The electrical contact-connection can be effected by metal layers, transparent conductive oxides (TCOs) and/or transparent conductive polymers (PEDOT-PSS, PANI).

A solar cell converts light energy into electrical energy. In this case, the term photoactive likewise denotes the conversion of light energy into electrical energy. In contrast to inorganic solar cells, in organic solar cells the light does not directly generate free charge carriers, rather excitons initially form, that is to say electrically neutral excitation states (bound electron-hole pairs). It is only in a second step that these excitons are separated into free charge carriers which then contribute to the electric current flow.

The advantage of such organic-based components over the conventional inorganic-based components (semiconductors such as silicon, gallium arsenide) are the in some instances extremely high optical absorption coefficients (up to 2×10⁵ cm⁻¹), thus affording the possibility of producing very thin solar cells with little outlay in terms of material and energy. Further technological aspects include the low costs, the possibility of producing flexible large-area components on plastic films, and the virtually unlimited possibilities for variation and the unlimited availability of organic chemistry.

One possibility for the realization of an organic solar cell that has already been proposed in the literature consists in a pin diode [Martin Pfeiffer, “Controlled doping of organic vacuum deposited dye layers: basics and applications”, PhD thesis TU-Dresden, 1999] having the following layer construction:
0. carrier, substrate,
1. bottom contact, normally transparent,
2. p-layer(s),
3. i-layer(s),
4. n-layer(s),
5. top contact.

In this case, n and p denote an n-type and p-type doping, respectively, which lead to an increase in the density of free electrons and holes, respectively, in the thermal equilibrium state. However, it is also possible for the n-layer(s) and p-layer(s) to be nominally undoped and to have preferably n-conducting and preferably p-conducting properties, respectively, only on account of the material properties (e.g. different mobilities), on account of unknown impurities (e.g. residual residues from the synthesis, decomposition or reaction products during the layer production) or on account of influences of the surroundings (e.g. adjacent layers, indiffusion of metals or other organic materials, gas doping from the surrounding atmosphere). In this sense, layers of this type should primarily be understood as transport layers. By contrast, the designation i-layer denotes a nominally undoped layer (intrinsic layer). In this case, one or a plurality of i-layers can consist layers either composed of one material, or a mixture composed of two materials (so-called interpenetrating networks or bulk heterojunction; M. Hiramoto et al. Mol. Cryst. Liq. Cryst., 2006, 444, pp. 33-40). The light incident through the transparent bottom contact generates excitons (bonded electron-hole pairs) in the i-layer or in the n-/p-layer. Said excitons can only be separated by very high electric fields or at suitable interfaces. Sufficiently high fields are not available in organic solar cells, with the result that all promising concepts for organic solar cells are based on the separation of excitons at photoactive interfaces. The excitons pass by diffusion to such an active interface, where electrons and holes are separated from one another. In this case, the material which takes up the electrons is designated as acceptor, and the material which takes up the hole is designated as donor. The separating interface can lie between the p- (n-) layer and the i-layer or between two i-layers. In the built-up electric field of the solar cell, the electrons are then transported away to the n-region and the holes to the p-region. Preferably, the transport layers are transparent or largely transparent materials having a large band gap (wide-gap) such as are described e.g. in WO 2004083958. In this case, the term wide-gap materials denotes materials whose absorption maximum lies in the wavelength range of <450 nm, and is preferably <400 nm.

Since the light always generates excitons first, and does not yet generate free charge carriers, the diffusion of excitons to the active interface with little recombination plays a critical part in organic solar cells. In order to make a contribution to the photocurrent, it is necessary, therefore, in a good organic solar cell, for the exciton diffusion length to distinctly exceed the typical penetration depth of the light, in order that the predominant part of the light can be utilized. Organic crystals or thin layers that are perfect structurally and with regard to chemical purity do indeed fulfill this criterion. For large-area applications, however, the use of monocrystalline organic materials is not possible and the production of multilayers with sufficient structural perfection is still very difficult to date.

If the i-layer is a mixed layer, then the task of light absorption is undertaken by either only one of the components or else both. The advantage of mixed layers is that the excitons generated only have to cover a very short path until they reach a domain boundary, where they are separated. The electrons and holes are respectively transported away separately in the respective materials. Since the materials are in contact everywhere with one another in the mixed layer, what is crucial in the case of this concept is that the separated charges have a long lifetime on the respective material and closed percolation paths for both types of charge carriers toward the respective contact are present from every location.

U.S. Pat. No. 5,093,698 discloses the doping of organic materials. By admixing an acceptor-like or donor-like doping substance, the equilibrium charge carrier concentration in the layer is increased and the conductivity is increased. According to U.S. Pat. No. 5,093,698, the doped layers are used as injection layers at the interface with respect to the contact materials in electroluminescent components. Similar doping approaches are analogously expedient for solar cells as well.

The literature discloses various possibilities for realization for the photoactive i-layer. Thus, the latter can be a double layer (EP0000829) or a mixed layer (Hiramoto, Appl. Phys. Lett. 58, 1062 (1991)). A combination of double and mixed layers is also known (Hiramoto, Appl. Phys. Lett. 58, 1062 (1991); U.S. Pat. No. 6,559,375). It is likewise known that the mixing ratio differs in different regions of the mixed layer (US 20050110005), or the mixing ratio has a gradient.

It is furthermore known from the literature that the photoactive mixed layers can be present in partly crystalline fashion (Hiramoto, MOLECULAR CRYSTALS AND LIQUID CRYSTALS, 444, 33-40 (2006)). In this case, the degree of crystallinity can be changed by the choice of substrate temperature during the vapor deposition. An increased substrate temperature normally leads to a greater crystalline proportion or larger crystallites. Alternatively, after layer production, too, the component can be subjected to an elevated temperature (Peumans, Nature, 425, 158 (2003)). This process normally likewise leads to an increased crystallinity. Another possibility for influencing the structure of an organic mixed layer consists in using the organic vapor-phase deposition technique (OVPD) (Rusu, Thin Solid Films, 516, 7160-7166 (2008); Rusu, Renewable Energy, 33, 254-258 (2008); Yang, Nature Materials, 4, 37-41, (2005)). Here, the organic material is vaporized in a gas flow. The gas flow then carries the molecules to the substrate. By choosing various parameters, it is possible to influence the structure of the deposited layers and mixed layers.

Furthermore, the literature discloses solar cells having an ip structure (Drechsel, Org. Electron., 5, 175 (2004); J. Drechsel, Synthet. Metal., 127, 201-205 (2002)). Here, the photoactive mixed layer is a mixed layer composed of ZnPc and C60. These two materials have very similar evaporation temperatures. Therefore, the problem described below does not occur in this system, with the result that the content of this patent is unaffected thereby.

Furthermore, tandem and multiple solar cells are known from the literature (Hiramoto, Chem. Lett., 1990, 327 (1990); DE 102004014046).

In the case of non-polymeric organic materials, so-called small molecules, the evaporation temperature in a vacuum is closely related to the intermolecular interactions. If said interactions are highly pronounced, this leads to an increased evaporation temperature.

Within the meaning of the invention, the term evaporation temperature is understood to mean that temperature which is required in order to achieve a vapor deposition rate of 0.1 nm/s at the position of the substrate for a given evaporator geometry (reference: source having a circular opening (diameter of 1 cm) at a distance of 30 cm from a substrate fitted perpendicularly thereabove) and a vacuum in the range of 10⁻⁴ to 10⁻¹⁰ mbar. In this case, it is unimportant whether evaporation in the narrower sense (transition from the liquid phase to the gas phase), or sublimation is involved in this case.

In the course of layer formation by vapor deposition, therefore, those structures in which the intermolecular interactions within the layer are maximized preferably arise, such that the interfaces which can enter into great interactions are avoided at the layer surface.

In the case of mixed layers, that has the effect that that component which has comparatively weak interaction forces preferably accumulates on the surface, that is to say that this component “floats” to a certain extent during layer formation. Materials having comparatively weak interaction between the molecules are normally distinguished by a low melting point (e.g. <100° C.) or a low glass transition temperature (e.g. <150° C.).

If the “more weakly interacting component” is the donor component of the mixed layer, there is a tendency for—in particular during growth on a heated substrate or during subsequent heat treatment—a very thin layer (i.e. at least one monolayer) to arise at the surface, which consists almost exclusively of the donor material. This segregation or this “floating” can also arise or be supported through other processes such as e.g. a solvent treatment (during the production of the layer or subsequently) or through the method of depositing a layer by means of organic vapor-phase deposition (OVPD). The monolayer of the donor component which “floated” consequently has poorer electron transport properties and impedes the process of transporting away photogenerated electrons in the case of a pin structure. By contrast, it is possible for photogenerated holes to be transported away in this direction without any problems, since, after all, the donor component is a preferably hole-transporting material.

The above-described problem occurs preferably when the donor material has an evaporation temperature in a vacuum which is at least 150° C. lower than the evaporation temperature of the acceptor material. However, it is also entirely possible for “floating” to take place even in the case of an evaporation difference of 100° C. or less.

Organic solar cells described in the literature which are made from vacuum deposition of non-polymeric organic molecules, so-called small molecules, are constructed, apart from a few exceptions (Drechsel, Org. Electron., 5, 175 (2004); J. Drechsel, Synthet. Metal., 127, 201-205 (2002)), such that the so-called bottom contact, on which the organic layers are deposited, forms the anode (if the structure comprises an exclusively hole-conducting or p-doped layer, the latter adjoins the bottom contact). The anode is generally a transparent conductive oxide (often indium tin oxide, abbreviated to ITO; however, it can also be ZnO:Al), but it can also be a metal layer or a layer composed of a conductive polymer. After the deposition of the organic layer system comprising the photoactive mixed layer, a—usually metallic—cathode is deposited.

This construction, designated here as non-inverted, has the consequence that the holes formed in the photoactive mixed layer have to be carried away toward the substrate (anode), while the photogenerated electrons have to move away from the substrate in the direction of the cathode. This is problematic, however, as described above, if the “floating” of the donor component occurs during the deposition or aftertreatment of the mixed layer.

This problem is manifested to a greater extent, the nearer to thermal equilibrium the growth of the mixed layer takes place. The advantage of an improved order in the volume during growth nearer to equilibrium (nanocrystalline instead of amorphous structure, cf. M. Hiramoto et al., Mol. Cryst. Liq. Cryst., 2006, 444, pp. 33-40; M. Rusu et al., Thin Solid Film, 2008, 516, pp. 7160-7166) is therefore counteracted by an increasing problem at the interface.

The problem therefore consists, in the case of a donor-acceptor combination wherein at least partial “floating” of the donor material in the mixed layer takes place, both in obtaining a good order in the mixed layer and at the same time incurring no transport problems at the interface of the mixed layer.

The invention is therefore based on the object of providing a photoactive component which overcomes the disadvantages described above and in this case has an increased efficiency of the component and as far as possible an improved lifetime. A further object of the invention is to provide a method for producing such a photoactive component.

The object is achieved by means of a photoactive component in accordance with claim 1. Advantageous embodiments are specified in the dependent claims.

According to the invention, this object is achieved by adopting an inverted layer sequence wherein the deposition takes place on the cathode (n-side at the bottom, e.g. n-i-p structure) and the photogenerated electrons thus have to leave the mixed layer in the direction toward the substrate, and the photogenerated electrons in the direction of the counterelectrode, both being possible without any problems.

The problem postulated here of the “floating” of a small number of monolayers is virtually impossible to prove spectroscopically using present-day means. Therefore, the problem has not been recognized heretofore and the solution to the problem as proposed here has not been taken into consideration heretofore by those skilled in the art.

One preferred embodiment of the invention exists as an organic nip solar cell or organic nipnip tandem solar cell or nip multiple solar cell, as presented in WO 2004083958.

For the above-described inverted structure (n-i-p, i-p or n-i structure) it may be that contact problems occur in the component at the electrode situated on the substrate and/or the counterelectrode: normally, in the traditional p-i-n structure, the electrode situated on the substrate has a contact to the p-layer and the counterelectrode has a contact to the n-layer. These contacts function very well, or that is to say the contact systems and contact materials have been optimized in the meantime, with the result that no losses occur here. As a possible solution for the inverted structure, the two new contact systems electrode/n-layer and p-layer/counterelectrode can now be optimized anew (e.g. through a suitable choice of the materials or suitable production conditions). Another solution possibility consists in incorporating a conversion contact (pn or np) at the electrodes, such that the old contact systems of electrode/p-layer and p-layer/counterelectrode are again obtained. Possible structures for this purpose include e.g. pnip, nipn or pnipn.

A further embodiment of the component according to the invention consists in the fact that a p-doped layer is also present between the first electron-conducting layer (n-layer) and the electrode situated on the substrate, with the result that a pnip or pni structure is involved, wherein the doping is preferably chosen to be high enough that the direct pn contact has no blocking effect, rather low-loss recombination occurs, preferably by means of a tunneling process.

In a further embodiment of the invention, a p-doped layer can also be present in the component between the photoactive i-layer and the electrode situated on the substrate, with the result that a pip or pi structure is involved, wherein the additional p-doped layer has a Fermi level situated at most 0.4 eV, but preferably less than 0.3 eV, below the electron transport level of the i-layer, with the result that low-loss electron extraction from the i-layer into this p-layer can occur.

A further embodiment of the component according to the invention consists in the fact that an n-layer system is also present between the p-doped layer and the counterelectrode, with the result that an nipn or ipn structure is involved, wherein the doping is preferably chosen to be high enough that the direct pn contact has no blocking effect, rather low-loss recombination occurs, preferably by means of a tunneling process.

In a further embodiment, an n-layer system can also be present in the component between the intrinsic, photoactive layer and the counterelectrode, with the result that an nin or in structure is involved, wherein the additional n-doped layer has a Fermi level situated at most 0.4 eV, but preferably less than 0.3 eV, above the hole transport level of the i-layer, with the result that low-loss hole extraction from the i-layer into this n-layer can occur.

A further embodiment of the component according to the invention consists in the fact that the component contains an n-layer system and/or a p-layer system, with the result that a pnipn, pnin, pipn or p-i-n structure is involved, which in all cases are distinguished by the fact that—independently of the conduction type—the layer adjoining the photoactive i-layer on the substrate side has a lower thermal work function than the layer adjoining the i-layer and facing away from the substrate, with the result that photogenerated electrons are preferably transported away toward the substrate if no external voltage is applied to the component.

In a further embodiment of the invention, a plurality of conversion contacts are connected in series with the result that e.g. an npnipn, pnipnp, npnipnp, pnpnipnpn or pnpnpnipnpnpn structure is involved.

In one preferred development of the structures described above, the latter are embodied as an organic tandem solar cell or multiple solar cell. Thus, the component can be a tandem cell composed of a combination of nip, ni, ip, pnip, pni, pip, nipn, nin, ipn, pnipn, pnin or pipn structures, wherein a plurality of independent combinations containing at least one i-layer are stacked one above another (cross-combinations).

In one particularly preferred embodiment of the structures described above, the latter is embodied as a pnipnipn tandem cell.

What is particularly important in stacked cells of this type is the balance of the generated currents in the individual cells, that is to say the number of absorbed photons converted into charge carriers. If the “floating” problem described above occurs e.g. in the case of a pinpin tandem cell having two different absorber systems in the case of a mixed layer, and if said mixed layer therefore generates less current or has a poorer filling factor and the tandem solar cell is thereby greatly diminished in its properties (the weaker partial cell, with its lower generated current or poorer filling factor (FF), limits the entire component, that is to say that the other partial cell, too, can no longer fulfill its potential), then the problem is solved according to the invention by changing to an inverted nipnip structure or to another of the structures described above.

In a further embodiment of the invention, in the case of a tandem or multiple cell, a certain number of the i-mixed layers are produced on a heated substrate (preferably between 70° C. and 140° C.) and the remaining i-mixed layers are produced while the substrate is at a lower temperature (preferably <60° C.) or room temperature. In this case, it is also possible for the i-mixed layers to be produced alternately on a heated substrate and at lower temperatures or room temperature by means of the substrate being alternately heated and cooled again.

In a further embodiment, the organic photoactive component is embodied as an organic solar cell embodied with an electrode and a counterelectrode and at least one organic photoactive i-layer system between the electrodes. This photoactive i-layer system contains at least one mixed layer composed of a donor material and an acceptor material, which form a donor-acceptor system. The donor and acceptor materials of the mixed layer contain non-polymeric materials, so-called small molecules. Furthermore, the donor material has an evaporation temperature in a vacuum which is at least 150° C. lower than the evaporation temperature of the acceptor material. The organic solar cell has an inverted layer sequence. The latter can be formed as an n-i-p, i-p or n-i structure composed in each case of an n-, i- or p-layer system, wherein the organic photoactive i-layer system is applied either directly on the cathode or on an electron-conducting n-material system.

In a further embodiment, the acceptor material in the mixed layer is present at least partly in crystalline form.

In a further embodiment, the donor material in the mixed layer is present at least partly in crystalline form.

In a further embodiment, both the acceptor material and the donor material in the mixed layer are present at least partly in crystalline form.

In a further embodiment, the acceptor material has an absorption maximum in the wavelength range of >450 nm.

In a further embodiment, the donor material has an absorption maximum in the wavelength range of >450 nm.

In a further embodiment, the photoactive i-layer system also contains further photoactive individual or mixed layers in addition to the mixed layer mentioned.

In a further embodiment, the n-material system consists of one or more layers.

In a further embodiment, the p-material system consists of one or more layers.

In a further embodiment, the n-material system contains one or more doped wide-gap layers. In this case, the term wide-gap layers defines layers having an absorption maximum in the wavelength range of <450 nm.

In a further embodiment, the p-material system contains one or more doped wide-gap layers.

In a further embodiment, light traps for enlarging the optical path of the incident light are formed in the active system.

In a further embodiment, the light trap is realized in that a doped wide-gap layer has a smooth interface with respect to the i-layer and a periodically microstructured interface with respect to the contact.

In a further embodiment, the light trap is realized by virtue of the fact that the component is constructed on a periodically microstructured substrate and the homogeneous function of the component, that is to say a short-circuit-free contact-connection and homogeneous distribution of the electric field over the entire area, is ensured by the use of a doped wide-gap layer. Ultrathin components have, on structured substrates, an increased risk of forming local short circuits, with the result that the functionality of the entire component is ultimately jeopardized by such an evident inhomogeneity. This risk of short circuits is reduced by the use of the doped transport layers.

In a further embodiment, the component contains a p-doped layer between the first electron-conducting layer (n-layer) and the electrode situated on the substrate, with the result that a pnip or pni structure is involved.

In a further embodiment, the component contains a p-doped layer between the photoactive i-layer and the electrode situated on the substrate, with the result that a pip or pi structure is involved, wherein the additional p-doped layer has a Fermi level situated at most 0.4 eV, but preferably less than 0.3 eV, below the electron transport level of the i-layer.

In a further embodiment, the component contains an n-layer system between the p-doped layer and the counterelectrode, with the result that an nipn or ipn structure is involved.

In a further embodiment, the component contains an n-layer system between the photoactive i-layer and the counterelectrode, with the result that an nin or in structure is involved, wherein the additional n-doped layer has a Fermi level situated at most 0.4 eV, but preferably less than 0.3 eV, above the hole transport level of the i-layer.

In a further embodiment, the component contains an n-layer system and/or a p-layer system, with the result that a pnipn, pnin, pipn or p-i-n structure is involved.

In a further embodiment, the additional p-material system and/or the additional n-material system contains one or more doped wide-gap layers.

In a further embodiment, the component contains still further n-layer systems and/or p-layer systems, with the result that e.g. an npnipn, pnipnp, npnipnp, pnpnipnpn or pnpnpnipnpnpn structure is involved.

In a further embodiment, one or more of the further p-material systems and/or of the further n-material systems contain(s) one or more doped wide-gap layers.

In a further embodiment, the component contains still further n-layer systems and/or p-layer systems, with the result that e.g. an npnipn, pnipnp, npnipnp, pnpnipnpn or pnpnpnipnpnpn structure is involved.

In a further embodiment, one or more of the further p-material systems and/or of the further n-material systems contain(s) one or more doped wide-gap layers.

In a further embodiment, the component is a tandem or multiple structure.

In a further embodiment, the component is a tandem cell composed of a combination of nip, ni, ip, pnip, pni, pip, nipn, nin, ipn, pnipn, pnin or pipn structures.

In a further embodiment, the organic materials used are small molecules. Within the meaning of the invention, the term small molecules is understood to mean monomers which can be evaporated and thus deposited on the substrate.

In a further embodiment, the organic materials are at least in part polymers, but at least one photoactive i-layer is formed from small molecules.

In a further embodiment, the acceptor material is a material from the group of fullerenes or fullerene derivatives (preferably C60 or C70) or a PTCDI derivative (perylene-3,4,9,10-bis(dicarboximide) derivative).

In a further embodiment, the donor material is an oligomer, in particular an oligomer according to WO2006092134, a porphyrin derivative, a pentacene derivative or a perylene derivative, such as DIP (di-indeno-perylene), DBP (di-benzo-perylene).

In a further embodiment, the p-material system contains a TPD derivative (triphenylamine-dimer), a spiro compound, such as spiropyrans, spirooxazines, MeO-TPD (N,N,N′,N′-tetrakis(4-methoxyphenyl)benzidine), di-NPB (N,N′-diphenyl-N,N′-bis(N,N′-di(1-naphthyl)-N,N′-diphenyl-(1,1′-biphenyl) 4,4′-diamines)), MTDATA (4,4′,4″-tris(N-3-methylphenyl-N-phenylamino)triphenylamine), TNATA (4,4′,4″-tris[N-(1-naphthyl)-N-phenylamino]triphenylamine), BPAPF (9,9-bis{4-[di-(p-biphenyl)aminophenyl]}fluorenes), NPAPF (9,9-bis[4-(N,N′-bisnaphthalen-2-ylamino)phenyl]-9H-fluorenes), spiro-TAD (2,2′,7,7′-tetrakis(diphenylamino)-9,9′-spirobifluorene), PV-TPD (N,N-di 4-2,2-diphenylethen-1-ylphenyl-N,N-di 4-methylphenylphenylbenzidines), 4P-TPD (4,4′-bis(N,N-diphenylamino)tetraphenyl), or a p-material described in DE102004014046.

In a further embodiment, the n-material system contains fullerenes such as, for example, C60, C70; NTCDA (1,4,5,8-naphthalenetetracarboxylic dianhydrides), NTCDI (naphthalenetetracarboxylic diimides) or PTCDI (perylene-3,4,9,10-bis(dicarboximide)).

In a further embodiment, the p-material system contains a p-dopant, wherein said p-dopant is F4-TCNQ, a p-dopant as described in DE10338406, DE10347856, DE10357044, DE102004010954, DE102006053320, DE102006054524 and DE102008051737, or a transition metal oxide (VO, WO, MoO, etc.).

In a further embodiment, the n-material system contains an n-dopant, wherein said n-dopant is a TTF derivative (tetrathiafulvalene derivative) or DTT derivative (dithienothiophene), an n-dopant as described in DE10338406, DE10347856, DE10357044, DE102004010954, DE102006053320, DE102006054524 and DE102008051737, or Cs, Li or Mg.

In a further embodiment, one electrode is embodied in transparent fashion with a transmission >80% and the other electrode is embodied in reflective fashion with a reflection of >50%.

In a further embodiment, the component is embodied in semitransparent fashion with a transmission of 10-80%.

In a further embodiment, the electrodes consist of a metal (e.g. Al, Ag, Au or a combination thereof), a conductive oxide, in particular ITO, ZnO:Al or some other TCO (transparent conductive oxide), a conductive polymer, in particular PEDOT/PSS poly(3,4-ethylenedioxythiophene)poly(styrenesulfonate) or PANI (polyaniline), or of a combination of these materials.

In a further embodiment, the organic materials used have a low melting point, preferably of <100° C.

In a further embodiment, the organic materials used have a low glass transition temperature, preferably of <150° C.

In a further embodiment, the organic materials used have a plurality of crystal phases and have a phase transformation temperature which is similar (+/−30° C.) to the substrate temperature during deposition or the temperature of the subsequent heat treatment. Heat treatment is understood to mean the heating of a solid to a temperature below the melting point. This takes place over a relatively long time (a few minutes up to a few days), in the course of which structural defects are compensated for and the crystal structure is improved in terms of the short- and long-range order. The process of melting and extremely slow cooling for setting the crystal structure is thus avoided.

In a further embodiment, the mixed layer is deposited by means of the the method of organic vapor-phase deposition (OVPD).

In a further embodiment, the mixed layer is deposited on a heated substrate, preferably having a temperature of >80° C.

In a further embodiment, the mixed layer is subjected to heat treatment after deposition, wherein the heat treatment temperature is at least 20° C. above the substrate temperature during deposition.

In a further embodiment, the mixed layer is treated with solvent vapors during or after production.

In a further embodiment, in a tandem or multiple cell, a certain number of i-layers are produced on a heated substrate (preferably between 70° C. and 140° C.), and the remaining i-layers are produced while the substrate is at a lower temperature (preferably <60° C.) or room temperature.

The invention will be explained more thoroughly below on the basis of exemplary embodiments. In the associated figures:

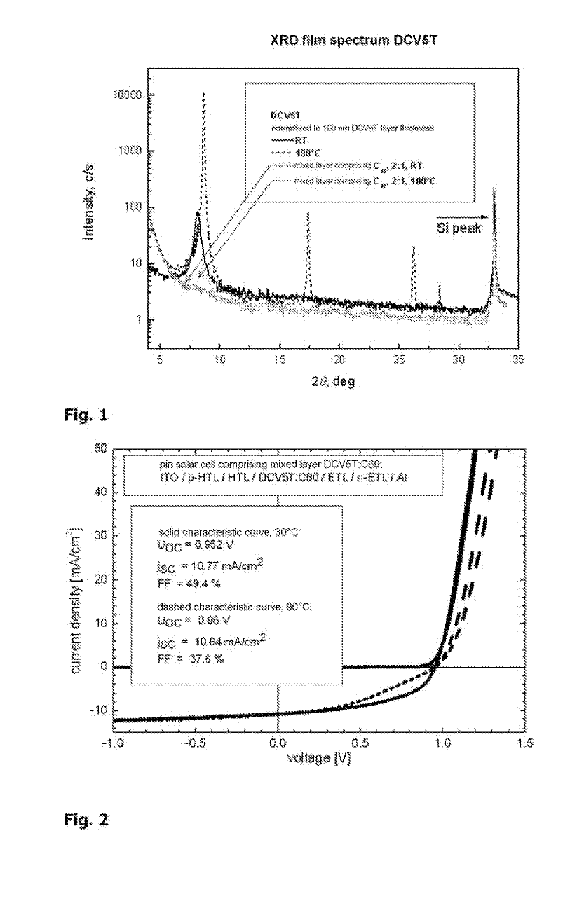

FIG. 1 shows an illustration of an X-ray diffraction measurement (XRD) on DCV5T films (on Si100),

FIG. 2 shows a current-voltage characteristic curve for a pin solar cell having a mixed layer DCV5T:C60 produced at a substrate temperature of 90° C. and at room temperature,

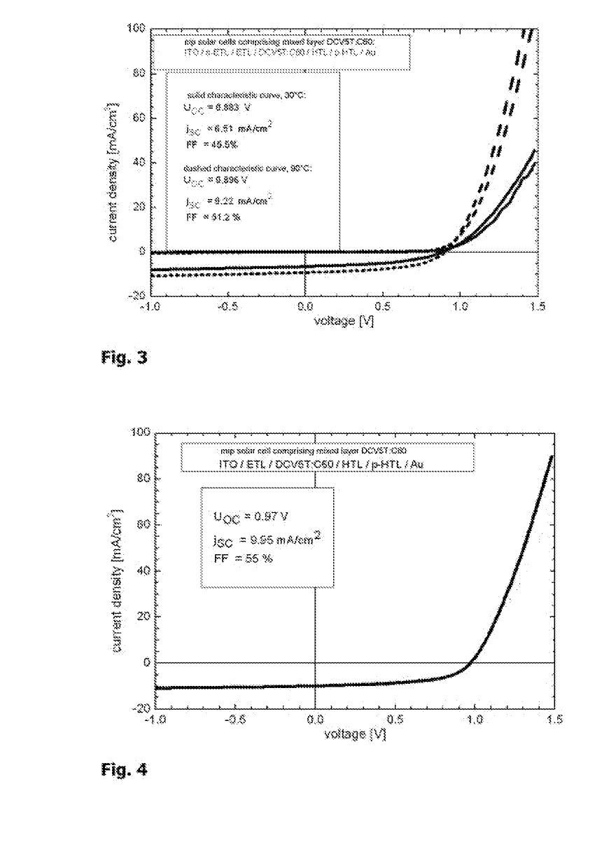

FIG. 3 shows a current-voltage characteristic curve for an nip solar cell having a mixed layer DCV5T:C60 produced at a substrate temperature of 90° C. and at room temperature,

FIG. 4 shows a current-voltage characteristic curve for an mip solar cell having a mixed layer DCV5T:C60 produced at a substrate temperature of 90° C.,

FIG. 5 shows a current-voltage characteristic curve for an mip solar cell having having different layer thicknesses of the mixed layers DCV5T:C60 produced at room temperature,

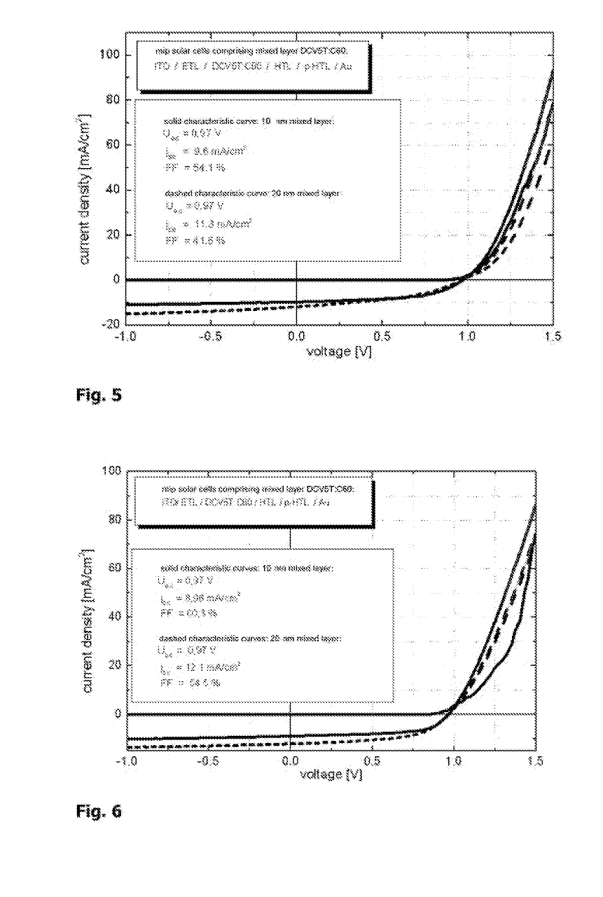

FIG. 6 shows a current-voltage characteristic curve for an mip solar cell having different layer thicknesses of the mixed layers DCV5T:C60 produced at a substrate temperature of 90° C., and

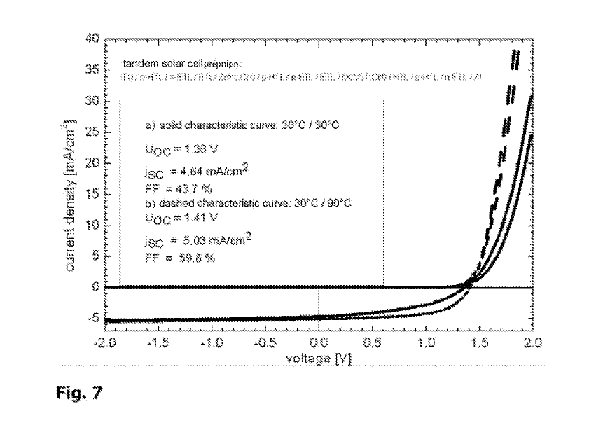

FIG. 7 shows a current-voltage characteristic curve for a pnipnipn tandem cell having mixed layers ZnPc:C60 and DCV5T:C60, wherein the mixed layers were produced at a substrate temperature of 30° C. and 90° C., respectively.

### EXEMPLARY EMBODIMENT A

Detection of crystallinity of the mixed layer DCV5T:C60, produced at a substrate temperature of 90° C.:

FIG. 1 shows an X-ray diffraction measurement (XRD) on DCV5T films (on Si100). The pure DCV5T layer (α,α′-bis(2,2-dicyanovinyl)quinquethiophene layer) (dashed and dark solid lines) exhibits a peak at 8.15° and 8.65°, respectively. The peak is significantly higher in the case of the sample which was applied to a heated substrate (100° C.) by vapor deposition (dashed line) in comparison with the sample which was deposited at room temperature (RT; dark solid line). The order or crystallinity has therefore increased significantly in the case of the 100° C. sample. The degree of crystallinity has decreased greatly in the case of the mixed layers comprising C60. The spectrum of the mixed layer at RT (RT=room temperature) exhibits no peak at all. By means of vapor deposition onto a heated substrate at 100° C., a crystallinity can also be obtained again in the mixed layer, albeit not yet to such a good degree as in the individual layers, for which reason only one peak arises here. For better differentiation, the curve profiles of the two mixed layers produced are assigned to the respective substrate temperatures by means of arrows.

### EXEMPLARY EMBODIMENT B

In a further exemplary embodiment, a pin solar cell having the construction ITO/p-HTL/HTL/DCV5T:C60/ETL/n-ETL/Al is used in FIG. 2. The mixed layer DCV5T:C60 is produced firstly at a substrate temperature of 90° C. (dashed characteristic curves, light and dark characteristic curves) and then at room temperature (30° C.; solid characteristic curves, light and dark characteristic curves).

The abbreviations used are defined as follows:
ETL: electron transport layer
HTL: hole transport layer
n-ETL: n-doped electron transport layer
p-HTL: p-doped hole transport layer

It can clearly be seen that the solar cell produced at 90° C. has a poor filling factor. Although the mixed layer DCV5T:C50 has a higher crystallinity here, this does not lead to a better component, but even to a worse component. The cause is a transport problem of the electrons from the mixed layer: between the mixed layer DCV5T:C60 and the overlying C60 layer, a very thin (presumably having a thickness of only one or a few monolayers) layer composed of DCV5T has formed, which impedes the process of transporting away the electrons. This problem is solved by turning round the pin structure and using an nip structure.

### EXEMPLARY EMBODIMENT C

In a further exemplary embodiment, an nip solar cell having the construction ITO/n-ETL/ETL/DCV5T:C60/HTL/p-HTL/Au is used in FIG. 3. The mixed layer DCV5T:C60 is produced firstly at a substrate temperature of 90° C. (dashed characteristic curves, light and dark characteristic curves) and then at room temperature (30° C.; solid characteristic curves, light and dark characteristic curves).

The solar cell produced at a substrate temperature of 90° C. is distinguished both by a higher short-circuit current and by a higher filling factor. The reason therefor is the increased crystallinity of the mixed layer DCV5T:C60. The very thin DCV5T layer that has again formed on the mixed layer does not have a disturbing effect in this case since it is now situated on the p-side of the component. On the contrary, this thin DCV5T in the case of this nip construction here can even contribute to the photocurrent and thus improve the properties of the component further.

### EXEMPLARY EMBODIMENT D

In a further exemplary embodiment, an mip solar cell having the construction ITO/ETL/DCV5T:C60/HTL/p-HTL/Au is used in FIG. 4. The mixed layer DCV5T:C60 was produced at a substrate temperature of 90° C. (light characteristic curve). In an mip structure, too, it is possible to realize a good component with a good filling factor.

### EXEMPLARY EMBODIMENT E

In a further exemplary embodiment, an mip solar cell having the construction ITO/C60/DCV5T:C60/p-BPAPF/p-ZnPc (p-zinc phthalocyanine)/Au with different layer thicknesses of the mixed layer is used in FIG. 5. The mixed layers DCV5T:C60 were produced at room temperature (30° C.). The layer thicknesses of the mixed layers are 10 nm (solid characteristic curves, light and dark characteristic curves) and 20 nm (dashed characteristic curves, light and dark characteristic curves).

The component with the thicker mixed layer is not better than the component with the thinner mixed layer, although the former absorbs more light. The reason is the poor crystallinity of the mixed layer produced at room temperature and the resultant problems when transporting away the charge carriers.

### EXEMPLARY EMBODIMENT F

In a further exemplary embodiment, an mip solar cell having the construction ITO/ETL/DCV5T:C60/HTL/p-HTL/Au with different layer thicknesses of the mixed layer is used in FIG. 6. The mixed layers DCV5T:C60 were produced at a substrate temperature of 90° C. The layer thicknesses of the mixed layers are 10 nm (solid characteristic curves, light and dark characteristic curves) and 20 nm (dashed characteristic curves, light and dark characteristic curves).

In this case, the component with the thicker mixed layer is clearly the better component: the short-circuit current has become significantly higher and the filling factor has become only slighter lower, with the result that the component with the thicker mixed layer has a higher efficiency.

### EXEMPLARY EMBODIMENT G

In a further exemplary embodiment, a pnipnipn tandem cell comprising mixed layers ZnPc:C60 and DCV5T:C60 is used in FIG. 7, wherein the mixed layers were applied at 30° C. and a substrate temperature of 90° C., respectively. The structure of the tandem cell is ITO/p-HTL/n-ETL/ETL/ZnPc:C60/p-HTL/n-ETL/ETL/DCV5T:C60/HTL/p-HTL/n-ET/Al.

For one solar cell (solid characteristic curve), the ZnPc:C60 mixed layer was produced at 30° C. and the DCV5T:C60 was also produced at a substrate temperature of 30° C. In the case of the second solar cell (dashed characteristic curve), by contrast, the ZnPc:C60 mixed layer was produced at 30° C. and the DCV5T:C60 was produced at a substrate temperature of 90° C. It can clearly be discerned that the second solar cell has a significant better filling factor and the component thus has a distinctly better efficiency.

1. An organic photoactive component comprising an electrode and a counterelectrode and at least one organic photoactive i-layer system between the electrodes and the counterelectrode wherein:
(i) the photoactive i-layer system contains at least one mixed layer,
(ii) said mixed layer contains at least one donor material and one acceptor material and the mixed layer thus forms a donor-acceptor system,
(iii) the donor material and the acceptor material of the mixed layer are non-polymeric materials,
(iv) the donor material has an evaporation temperature in a vacuum which is at least 150° C. lower than an evaporation temperature of the acceptor material, and
(v) has an inverted layer sequence composed of an n-i-p, i-p or n-i structure composed in each case of an n-, i- or p-layer system, wherein the organic photoactive i-layer system is applied directly on a cathode or on an electron-conducting n-material system.

2. The photoactive component according to claim 1, wherein the component comprises a p- and/or n-material system consisting of one or more layers.

3. The photoactive component according to claim 2, wherein the p- and/or n-material system contains one or more doped wide-gap layers having an absorption maximum in a wavelength range of <450 nm.

4. The photoactive component according to claim 1, wherein light traps for enlarging an optical path of incident light are formed in the photoactive system.

5. The photoactive component according to claim 4, wherein a light trap is realized by a doped wide-gap layer having a smooth interface with respect to the i-layer and a periodically microstructured interface with respect to a contact.

6. The photoactive component according to claim 4, wherein a light trap is realized by construction of the component on a periodically microstructured substrate and a short-circuit-free contact-connection and homogeneous distribution of electric field over an entire area is ensured by use of a doped wide-gap layer.

7. The photoactive component according to claim 1, wherein the component contains a p-doped layer between a first electron-conducting n-layer and the electrode situated on a substrate, resulting in a pnip or pni structure is involved.

8. The photoactive component according to claim 7, wherein the component contains an additional p-doped layer between the photoactive i-layer and the electrode situated on the substrate, resulting in a pip or pi structure, and the additional p-doped layer has a Fermi level situated at most 0.4 eV below an electron transport level of the i-layer.

9. The photoactive component according to claim 1, wherein the component contains an n-layer system between the p-doped layer and the counterelectrode, resulting in an nipn or ipn structure.

10. The photoactive component according to claim 9, wherein the component contains an additional n-layer system between the photoactive i-layer and the counterelectrode, resulting in an nin or in structure, and the additional n-doped layer has a Fermi level situated at most 0.4 eV above the hole transport level of the i-layer.

11. The photoactive component according to claim 1, wherein the component contains an additional n-layer system and/or an additional p-layer system, resulting in a pnipn, pnin, pipn or p-i-n structure.

12. The photoactive component according to claim 11, wherein the additional layer system and/or the additional layer system contains one or more doped wide-gap layers.

13. The photoactive component according to claim 11, wherein the component contains further n-layer systems and/or further p-layer systems, resulting in an npnipn, pnipnp, npnipnp, pnpnipnpn or pnpnpnipnpnpn structure.

14. The photoactive component according to claim 13, wherein one or more of the further p-layer systems and/or of the further n-layer systems contain(s) one or more doped wide-gap layers.

15. The photoactive component according to claim 1, wherein the component is a tandem or multiple cell composed of a combination of nip, ni, ip, pnip, pni, pip, nipn, nin, ipn, pnipn, pnin or pipn structures.

16. The photoactive component of claim 8, wherein the additional p-doped layer has a Fermi level situated less than 0.3 eV below the electron transport level of the i-layer.

17. The photoactive component of claim 10, wherein the additional n-doped layer has a Fermi level situated less than 0.3 eV above the hole transport level of the i-layer.
